(19) United States
(12) Patent Application Publication
(10) Pub. No.: US 2013/0113509 A1
(43) Pub. Date: May 9, 2013

(54) Temperature Control System for IC Tester

(71) Applicants: Xin-Yi WU, Taoyuan County (TW); Jui-Che Chou, Taoyuan County (TW); Meng-Kung Lu, Taoyuan County (TW); Chin-Yi Ou Yang, Taoyuan County (TW)

(72) Inventors: Xin-Yi WU, Taoyuan County (TW); Jui-Che Chou, Taoyuan County (TW); Meng-Kung Lu, Taoyuan County (TW); Chin-Yi Ou Yang, Taoyuan County (TW)

(21) Appl. No.: 13/418,124

(22) Filed: Mar. 12, 2012

(30) Foreign Application Priority Data
Nov. 4, 2011 (TW) 100140371

(51) Int. Cl. G01R 31/00

(52) U.S. Cl. 324/750.03

(57) ABSTRACT

A temperature control system for IC tester, comprising: a test socket; a compressing device including a heat exchanger and a thermoelectric cooler (TEC); and a test head having a temperature sensor. The test head is configured at the front end of the compressing device such that, upon placing at least one device under test (DUT) onto the test socket, the test head coerces tightly one of the DUTs through downward pressure from the compressing device thereby allowing the temperature sensor to detect the surface temperature of the DUT to obtain a temperature signal, and then feed such a temperature signal back to a control processing unit for operations to generate a linear control signal thus that, through the control of the linear control signal, the heat absorption and heat discharge functions of the TEC are enabled to further control the temperature of the DUT within a determined range.

### BACKGROUND OF THE INVENTION

1. Field of the Invention

The present invention generally relates to a temperature control system for IC tester; in particular, the present invention relates to a temperature control system for effectively controlling the temperature of a device under test (DUT) within a determined temperature range during tests on the electronic device.

2. Description of Related Art

Integrated circuit (IC) devices allow to integrate and miniaturize massive electronic circuit components and computation speeds as well as product performances thereof are still incessantly elevated, so computational operations requiring combinations of many large-scaled electronic circuits to be successfully completed in the past can be entirely done by such IC devices. Seeing that the IC component yield may directly impact the performance, lifespan and reliability of such types of electronic devices, for IC manufacture, package and test industries, therefore, electric or in-field tests will be performed after each phase of the manufacture processes to inspect and determine whether the ICs conform to user's specification requirements during such fabrication stages in order to ensure the product quality. At present, it is possible to use an automatic IC tester to detect defected products and further sort them out. However, all types of electronic products are still inevitably confronted with the heat sinking issue, and once the heat generated along with operations or illuminations of the electronic device can not be successfully brought out, then the high temperature as the electronic device works can not be effectively reduced, which, to a less serious extent, may cause problems like shortened product lifespan, reduced product performance or other adverse influences on relevant peripheral elements; or otherwise, in the worst case, the thermal runaway issue or even exposure to immediate danger may directly occur. As such, heat dissipation is a subject never to be overlooked.

For this reason, currently it is common to utilize various elements such as cooling fins, fans or even the thermoelectric cooler (TEC), or a combination of said devices, to discharge the heat energy near the heat-generating components and reduce temperature in proximity of these components. However, the contact area or the size of transduction cross-section indicates a critical restriction factor for thermal transductions, no matter between the heat-generating component and the contact face of heat sink, from the contact face to the metal fin or else between the air and the metal fin. That is, within a narrow space, it is not possible to install a heat sink or cooling fin of larger size, so the heat dissipation efficiency will be undesirably compromised. But, on the other hand, as the size of electronic device is required to become slimmer and smaller to go with market trends, issues concerning how to ensure heat dissipation efficiency under a condition of significantly reduced space are actually very challenging for engineers in charge of electronic device internal space planning and circuit layouts.

In conventional technologies, it is general to perform thermal exchanges on self-heating generated during tests with a certain mechanism like stand-alone refrigerating device or alternatively in conjunction with cooling fins and so forth, such that the IC device can be maintained within a supposed temperature range upon testing. In pace with the evolution of IC device technologies, whereas, the precision in temperature control for test operations as well as efficiency thereof should be accordingly ameliorated. Unfortunately, the aforementioned refrigerating device can not provide real-time temperature control capabilities along with test operations, solutions are hence proposed. By referring to the specification and drawings of ROC Patent Publication No. 1342958, it can be appreciated that a thermoelectric cooler (TEC) 15 is installed under a press down tool set of a press down lever inside the refrigerating temperature control device 1, and a sensor 11 retractably contacting an electronic device is installed in protrusion at the end of the press down tool set (as shown in FIG. 1). The sensor 11 detects the temperature of the electronic device and then transfers a corresponding temperature signal to a control unit 13 through a signal transformer 12. Upon reception of the temperature signal, the control unit 13 performs operations and comparisons along with a database and transfers a signal indicating the required electric current amount to a power supply 14 thereby controlling the electric current outputted to the TEC 15 by the power supply 14. Consequently, upon using the press down lever to apply downward pressure on the electronic device for tests, the TEC 15 performs thermal exchanges on self-heating generated by the electronic device during tests such that it is possible to precisely control the test operations in real-time within a smaller test temperature range.

Although the aforementioned method is able to control the test temperature range within a smaller range, controlling the TEC through keeping adjusting the output power, however, needs to repeatedly activate and deactivate the TEC, which may lead to reduced lifespan of the TEC due to consistent output power fluctuation. As a result, for those semiconductor manufacturers in need of consistent performance of test operations, this may become a very unstable factor, and unexpected failures of TEC may also cause serious losses with regards to manufacture costs.

It would be, therefore, an optimal solution in case that it is possible to use a linear control signal to control the TEC, rather than the conventional ON/OFF control approach, to regulate the TEC thereby elongating the lifespan thereof.

### SUMMARY OF THE INVENTION

An objective of the present invention is to provide a temperature control system for IC tester which allows to, upon using a compressing device to coerce tightly a device under test (DUT), detect the surface temperature of the DUT and generate a linear control signal so as to control the temperature of the DUT within a determined range through heat absorption and heat discharge functions of a thermoelectric cooler (TEC).

Another objective of the present invention is to, as performing temperature regulations on the TEC through the linear control signal, provide better controls on the surface temperature of the DUT by means of the TEC so as to prevent possible failure in the TEC caused by the conventional ON/OFF control method.

A temperature control system for IC tester according to the present invention enabling achievement of the aforementioned objectives comprises a test socket; a compressing device, including a heat exchanger and a thermoelectric cooler (TEC); a test head, having a temperature sensor and installed at the front end of the compressing device; wherein, upon placing at least one device under test (DUT) onto the test socket, the test head coerces tightly one of the DUTs through downward pressure from the compressing device thereby allowing the temperature sensor to detect the surface temperature of the DUT to obtain a temperature signal, and then feed the obtained temperature signal back to a control processing unit for operations to generate a linear control signal, so the electric current inputted to the TEC can be under the control of the linear control signal in order to control the temperature of the DUT within a determined range by means of heat absorption and heat discharge functions of the TEC.

More specifically, the control processing unit comprises a combination of a controller and an amplifier, wherein the controller receives the fed-back temperature signal and the amplifier generates a linear control signal.

More specifically, the linear control signal is a set of pulse width modulation (PWM) signals.

More specifically, the control processing unit further includes a proportional-integral-derivative (PID) controller for comparing the temperature signal obtained from detections on the surface temperature of the DUT by the temperature sensor with the determined range; in addition, the determined range is set by a control device which is also used to receive the temperature signal obtained from detections on the surface temperature of the DUT by the temperature sensor.

### BRIEF DESCRIPTION OF THE DRAWINGS

FIG. 1 shows a temperature control architecture diagram for a conventional refrigerating temperature control device; and

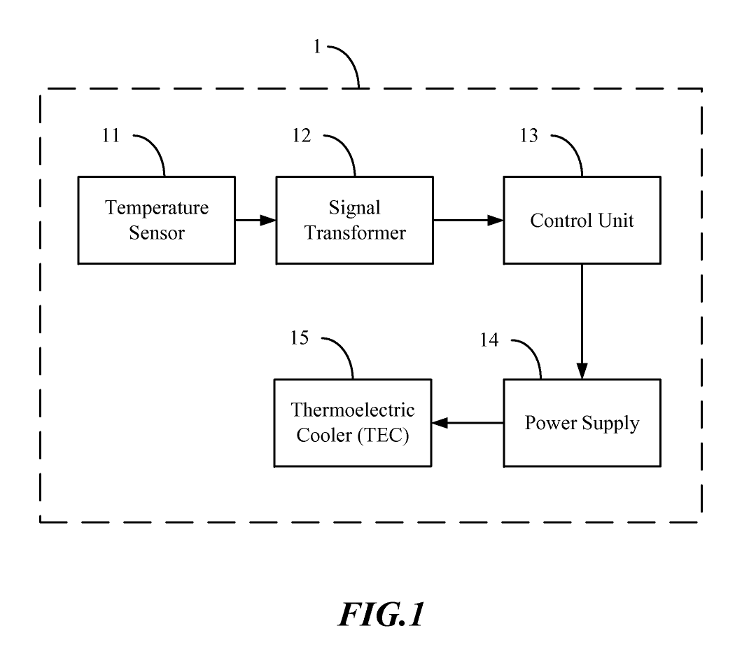

FIG. 2 shows an architecture diagram of a temperature control system for IC tester in accordance with the present invention.

### DETAILED DESCRIPTION OF THE PREFERRED EMBODIMENTS

The aforementioned and other technical contents, aspects and effects in relation with the present invention can be clearly appreciated through the detailed descriptions concerning the preferred embodiments of the present invention in conjunction with the appended drawings.

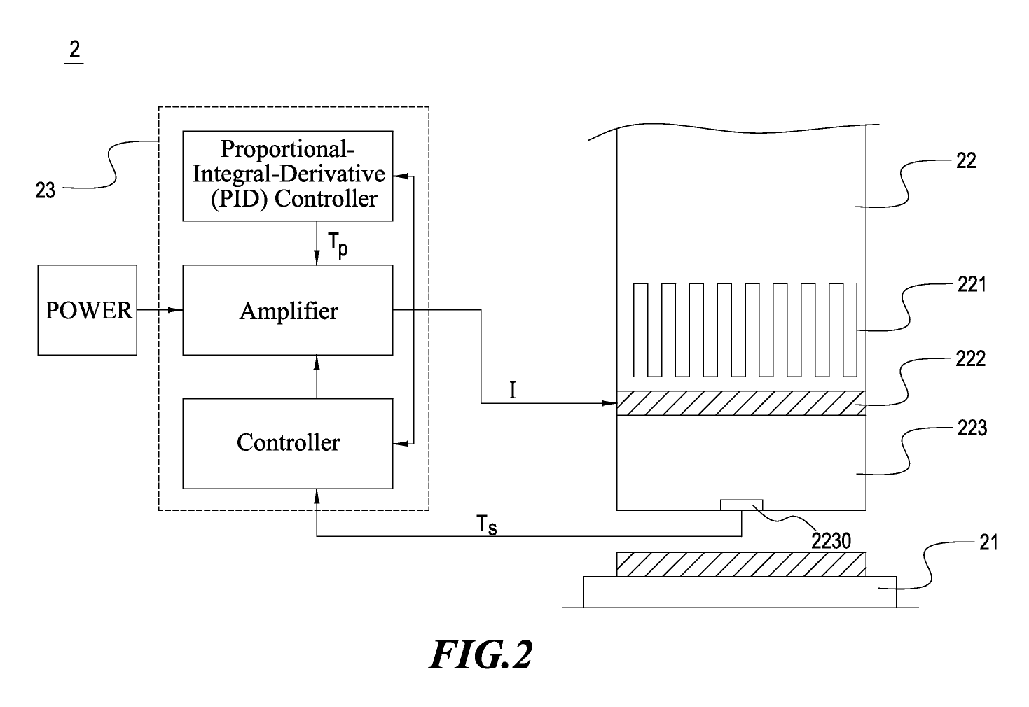

Refer now to FIG. 2, wherein an architecture diagram of a temperature control system for IC tester in accordance with the present invention is shown. It can be seen from the Figure that the temperature control system for IC tester 2 mainly comprises a test socket 21; a compressing device 22 including a heat exchanger 221 and a thermoelectric cooler (TEC) 222; and a test head 223 having a temperature sensor 2230 and installed at the front end of the compressing device 22. Therefore, upon placing at least one device under test (DUT) onto the test socket 21, the test head 223 coerces tightly one of the DUTs through downward pressure from the compressing device 22 thereby allowing the temperature sensor to detect the surface temperature of the DUT to obtain a temperature signal Ts, and then feed such a temperature signal Ts back to a control processing unit 23 for operations.

The DUT is placed onto the test socket 21 in an automatic relocation way and not yet tightly attached to the test socket 21 at this moment, so a coercive force applied by the compressing device 22 and alignment of the test head 223 are required to start test operations on the DUT; meanwhile, the temperature sensor 2230 installed at the front end of the test head 223 contacts the surface of the DUT to detect the temperature of the target area in real-time. The temperature sensor 2230 may be in a form of contact-induction-feedback, directly fixed to the test head, or otherwise configured as a probe pin by using elastic components, which is not restrictive in any aspect.

Herein the control processing unit 23 includes a controller 231, an amplifier 232 as well as a proportional-integral-derivative (PID) controller 233. The controller 231 receives the temperature signal Ts fed back from the temperature sensor 2230 and compares, through the PID controller 233, the received temperature signal Ts with a temperature range set by a control device (not shown), then outputs a stable linear control signal Tp (e.g., a pulse width modulation (PWM) signal) in conjunction with the amplifier 232. Under the control of the amplifier 232 and the linear control signal Tp, the electric current I inputted to the TEC 222 can be accordingly adjusted so as to control the temperature of the DUT within a determined range during tests by means of regulating the heat absorption and heat discharge functions of the TEC 222. The aforementioned temperature control within the determined range means that the electric current I inputted to the TEC can be adjusted with regards to its current value, negative/positive feature etc., after comparison with the fed-back temperature signal Ts.

The above-said control device, in addition to setting the temperature range, can be also used to receive the temperature signal obtained from detections on the surface temperature of the DUT by the temperature sensor.

Furthermore, upon coercing tightly the temperature sensor of the test head 223 onto the DUT, it is possible to consistently transfer the temperature signal indicating the surface temperature of the DUT to the control processing unit 23, and after operations, control in real-time the working temperature of the TEC 222 through the linear control signal output, so the present invention enables real-time adjustments on the operating status of the TEC 222 in correspondence with the surface temperature of the DUT.

Compared with prior art, the temperature control system for IC tester provided by the present invention can offer the following advantages:
1. in the present invention, each test unit is installed with an independent closed-loop temperature control system, and consequently, only one target temperature range is required in order to perform proportional-integral-derivative controls according to the difference between the system actual temperature fed back from the temperature sensor and the target temperature such that the present invention can rapidly and stably maintain the temperature within the target temperature range; and
2. the control processing unit according to the present invention provides a stable linear control signal output in order to eliminate the impact caused by incessant activate/deactivate actions in the TEC so as to prolong the lifespan thereof.

By way of the aforementioned detailed descriptions for the preferred embodiments according to the present invention, it is intended to better illustrate the characters and spirit of the present invention rather than restricting the scope of the present invention to the preferred embodiments disclosed in the previous texts. Contrarily, the objective is to encompass all changes and effectively equivalent arrangements within the scope of the present invention as delineated in the following claims of the present application.

1. A temperature control system for IC tester, comprising a test socket, a compressing device including a heat exchanger and a thermoelectric cooler (TEC), and a test head having a temperature sensor, wherein the test head is configured at the front end of the compressing device such that, upon placing at least one device under test (DUT) onto the test socket, the test head coerces tightly one of the DUTs through downward pressure from the compressing device, characterized in that: when the test head coerces tightly one of the DUTs, the temperature sensor detects the surface temperature of the DUT to obtain a temperature signal, and then such a temperature signal is fed back to a control processing unit for operations to generate a linear control signal, so the electric current inputted to the TEC is under the control of the linear control signal in order to control the temperature of the DUT within a determined range by means of heat absorption and heat discharge functions of the TEC.

2. The temperature control system for IC tester according to claim 1, wherein the control processing comprises a controller and an amplifier, in which the controller receives the fed-back temperature signal and the amplifier generates a linear control signal.

3. The temperature control system for IC tester according to claim 1, wherein the linear control signal is a set of pulse width modulation (PWM) signals.

4. The temperature control system for IC tester according to claim 1, wherein the control processing unit further includes a proportional-integral-derivative (PID) controller for comparing the temperature signal obtained from detections on the surface temperature of the DUT by the temperature sensor with the determined range.

5. The temperature control system for IC tester according to claim 4, wherein the determined range is set by a control device which is also used to receive the temperature signal obtained from detections on the surface temperature of the DUT by the temperature sensor.

6. The temperature control system for IC tester according to claim 2, wherein the linear control signal is a set of pulse width modulation (PWM) signals.
